(19) United States
(12) Patent Application Publication
(10) Pub. No.: US 2014/0042422 A1
(43) Pub. Date: Feb. 13, 2014

(54) INTERNAL OPTICAL EXTRACTION LAYER FOR OLED DEVICES

(71) Applicants: Gary S. Silverman, King of Prussia, PA (US); Roman K. Korotkov, King of Prussia, PA (US); Ryan C. Smith, Schwenksville, PA (US); Jun Liu, Richland, WA (US); Daniel J. Gaspar, Richland, WA (US); Asanga B. Padmaperuma, Richland, WA (US); Liang Wang, Milpitas, CA (US); Birgit Schwenzer, Richland, WA (US); James S. Swensen, Paul, ID (US)

(72) Inventors: Gary S. Silverman, King of Prussia, PA (US); Roman K. Korotkov, King of Prussia, PA (US); Ryan C. Smith, Schwenksville, PA (US); Jun Liu, Richland, WA (US); Daniel J. Gaspar, Richland, WA (US); Asanga B. Padmaperuma, Richland, WA (US); Liang Wang, Milpitas, CA (US); Birgit Schwenzer, Richland, WA (US); James S. Swensen, Paul, ID (US)

(73) Assignees: Battelle Memorial Institute, Richland, WA (US); Arkema Inc., King of Prussia, PA (US)

(21) Appl. No.: 14/111,254

(22) PCT Filed: Mar. 26, 2012
(86) PCT No.: PCT/US12/30508

§ 371 Date: Oct. 11, 2013

Related U.S. Application Data
(60) Provisional application No. 61/474,522, filed on Apr. 12, 2011.

(51) Int. Cl. H01L 51/52

(52) U.S. Cl. CPC H01L 51/5275
USPC 257/40; 257/98; 438/29

(57) ABSTRACT

A light-emitting device, which improves the light output of organic light emitting diodes (OLEDs), includes at least one porous metal or metalloid oxide light extraction layer positioned between the substrate and the transparent conducting material layer in the OLED. The index of refraction of the light extraction layer and the light scattering may be tuned by changing the pore size, pore density, doping the metal oxide, adding an insulating, conducting or semiconducting component, or filling the pores, for example. A method for forming the light-emitting device includes forming at least one light extraction layer comprising a porous metal or metalloid oxide on a substrate, for example, using atmospheric pressure chemical vapor deposition (APCVD), and subsequently, forming a transparent conducting material on the light extraction layer.

### STATEMENT REGARDING FEDERALLY SPONSORED RESEARCH OR DEVELOPMENT

This invention was developed in conjunction with Battelle Memorial Institute, Pacific Northwest National Laboratory (PNNL), a U.S. Department of Energy (DOE) government research laboratory.

### FIELD OF THE INVENTION

The invention relates to light-emitting devices, such as organic light-emitting diodes (OLEDs), having at least one light extraction layer and methods of making the same.

### BACKGROUND OF THE INVENTION

Light emitting diodes (LEDs) are known and are used in many applications, such as in displays and status indicators. LEDs may be formed from organic and/or inorganic materials. Inorganic LEDs include an inorganic light emitting material for a light emitting layer, typically an inorganic semiconductor material, such as gallium arsenide. Organic LEDs (OLEDs) typically include an organic material for the light emitting layer and charge transport. Inorganic LEDs may provide bright and durable point light sources, whereas OLEDs may provide large area surface emitting light sources. Both forms of solid-state lighting represent significant operational energy savings versus traditional incandescent technology.

OLEDs generally include thin organic layers, either polymers or small molecules, sandwiched between a pair of electrodes. Typically, at least one of the electrodes is transparent to the emitted light. Light emission out of the device, however, may be reduced due to internal reflection of light within the various layers of the OLED. In fact, the light emitted from typical OLEDs, in the absence of any light extraction technologies, can be on the order of about 10-26% of the total emitted light. Thus, there is a need to improve the light extraction or output of OLED devices, especially over the entire visible light spectrum, to provide for more energy efficient lighting.

### SUMMARY OF THE INVENTION

The present invention provides for a special internal light extraction layer or layers positioned between two adjacent layers in a light-emitting device. In particular, the light extraction layer or layers may be positioned between the substrate and the transparent conducting material (e.g., transparent conducting oxide (TCO)) of the light-emitting device. This light extraction layer having a porous metal oxide or metalloid oxide structure reduces total internal reflection, wherein the pores decrease the index of refraction of the metal oxide or metalloid oxide, in order to reduce index of refraction mismatch at the transparent conducting oxide (TCO)-substrate interface (or other interfaces within the light-emitting device) leading to more of the emitted light being extracted from the OLED device at a given voltage and current. The light extraction layer or layers may improve the light output of white OLEDs without affecting the operating voltage. Additionally, the light extraction layer(s) may improve light scattering and reduce or minimize plasmon absorption (i.e., light is extracted from the device before it quenches). Calculations suggest the external quantum efficiency (EQE) of a device, defined as the number of photons detected external to the device per unit charge injected, can be increased from approximately 20% to 70% for a single wavelength device (an improvement of about 250% or 3.5×). Thus, a higher power efficiency can be obtained (e.g., up to 87 lumens per watt (lm/W) as compared to about 25 lm/W with current technology). Alternatively, the increased brightness can be used to reduce the required drive current for the same light output. This in turn improves the lifetime, leading to an increase of up to 480% in OLED lifetime (assuming an acceleration factor of 1.4) at the same brightness as a device without the light extraction layer outcoupling structure.

In order to further improve the light output of a light-emitting device, the index of refraction and/or the light scattering of the porous metal oxide structure may be tuned using one or several different parameters including, but not limited to: (i) changing the pore size, pore density, or pore orientation or structure; (ii) compositional doping, (iii) adding an insulating, conducting, or semiconducting component, (iv) filling the pores, for example, with low index materials; vi) changing the thickness or number of layers, index of refraction of component layers comprising the light extraction layer or combinations thereof. Moreover, the index of refraction and/or light scattering may be tuned by selection of an appropriate template and/or annealing conditions during a sol-gel or aero-gel/gas phase synthesis of the light extraction layer(s). Unlike prior light extraction devices and techniques which may only exhibit improved light output at certain limited wavelengths or colors in the visible spectrum, the present invention may be tuned to improve light output over the entire visible spectrum (e.g., about 400 nm to 800 nm or the entire white light spectrum). Additionally, light scattering may be improved and a desired refractive index may be obtained for the light extraction layer(s).

According to one aspect of the present invention, a light-emitting device, which improves the light output of white organic light emitting diodes (OLEDs), for example, includes at least one porous metal or metalloid oxide light extraction layer positioned between two adjacent layers in a light-emitting device. In an exemplary embodiment, the at least one porous metal or metalloid oxide light extraction layer, such as a mesoporous titania, is sandwiched between the substrate and the transparent conducting material layer in the light-emitting device.

According to another embodiment of the present invention, a method for forming the light-emitting device includes forming at least one light extraction layer comprising a porous metal or metalloid oxide on a substrate, for example, using atmospheric pressure chemical vapor deposition (APCVD), and subsequently, forming a transparent conducting material on the light extraction layer(s). Other suitable layers known in the art may also be applied to form the light-emitting device, such as an OLED.

According to another embodiment of the present invention, a method of a light extraction layer in a light-emitting device comprises varying at least one of pore size and pore density of a porous metal or metalloid oxide to obtain at least one refractive index and light scattering for at least one light extraction layer comprising the porous metal or metalloid oxide, wherein the light extraction layer(s) is positioned between a substrate and a transparent conducting oxide.

### BRIEF DESCRIPTION OF THE DRAWINGS

The invention may be understood from the following detailed description when read in connection with the accompanying drawing in which:

FIG. 1 illustrates a light-emitting device according to the prior art;

FIG. 2 depicts a light-emitting device including a light extraction layer according to one aspect of the present invention;

FIG. 3 illustrates a substrate for a light-emitting device having a light extraction layer with a graded refractive index according to another aspect of the present invention;

FIG. 4 depicts the typical layers in an OLED and also having a light extraction layer according to one embodiment of the present invention;

FIG. 5 illustrates an embodiment of a substrate for a light-emitting device having more than one light extraction layer each having different pore size and pore density, which results in different indices of refraction;

FIG. 6 provides examples of normalized light scattering for 90 degree incidence showing 2D and 3D images for (a) a glass substrate only; (b) a transparent conducting material on a glass substrate; (c) an internal light extract layer; and (d) two internal light extraction layers;

FIG. 7 shows N₂ adsorption isotherms and pore diameter distribution (insets) for porous metal oxide materials annealed at (a) 350° C., (b) 400° C. and (c) 450° C., respectively;

FIG. 8 shows (a) refractive indices (mesoporous TiO₂ films on Si substrates) and (b) pore sizes (mesoporous TiO₂ bulk material) for TiO₂-F127 (□), TiO₂-P123 (O), and TiO₂-2xP123 (Δ), which are plotted versus the annealing temperature of the material;

FIG. 9 shows an embodiment of the invention including two light extraction layers comprising TiO₂ between a glass layer and a doped zinc oxide (DZO) layer; and

FIG. 10 shows another embodiment of the invention including two light extraction layers comprising TiO₂ on a glass layer.

The reference numbers correlate to the following elements in the Figures:
100: Light-Emitting Device;
102: Substrate;
103: Light Extraction Layer(s);
104: Transparent Conducting Material, Transparent Conducting Oxide (TCO), Anode, or Electrode;
106: OLED Stack;
106a: Hole Injection Layer;
106b: Hole Transport Layer;
106c: Emitter Layer or Organic Layer;
106d: Electronic Transport Layer; and
108: Cathode or Electrode.

### DETAILED DESCRIPTION OF THE INVENTION

Aspects of the present invention include porous metal or metalloid oxide light extraction layer(s) used in light-emitting devices, tuning the properties of the light extraction layer(s) to achieve a desired refractive index and/or light scattering, and methods of making the devices. Although the light-emitting device may include OLED, photovoltaic, or any other suitable devices, the primary application for the light extraction layer is an OLED light.

As used herein, a “light extraction layer” or LEL is a layer (e.g., a thin film, skin, covering, or coating), which helps to extract or increase the output of light emitted from a light-emitting device, such as an OLED. The light extraction layer or layers may improve light scattering (e.g., a change in the direction of motion of a photon or subatomic particle as the result of a collision or interaction) effectively widening the angle of light escape from the OLED device, subsequently minimizing plasmon absorption (e.g., extracting light before the light is quenched within the device) by reducing the number of reflections required to get the light out of the device. The thickness of the light extraction layer(s) is not especially limited and may be any suitable thickness useful to one of ordinary skill in the art.

As used herein, a “transparent conducting material” (“TCM”) or “transparent conducting oxide” (“TCO”) is a transparent electrode (typically, the anode) in light-emitting devices and is well known to one skilled in the art. Transparent conducting materials or TCOs display a combination of both electrical conductivity and optical transparency (e.g., having greater than 85% transmission across the visible light spectrum). Transparent conducting materials are generally in the form of a layer, a coating, or a film and may be interchangeable with transparent conducting films (TCFs). The transparent conducting material may be of any suitable material including, but not limited to, doped or undoped metal oxides. Preferably, the transparent conducting material is a TCO, such as a doped metal oxide including, for example, a doped zinc oxide or indium tin oxide (ITO). In one embodiment, the transparent conducting oxide acts as an overlayer over the light extraction layer (e.g., the underlayer). Although the transparent conducting oxide is described in detail herein, it is envisioned that any suitable electrode may be selected and used in the light-emitting devices, such as transparent conducting polymers or other transparent conducting materials.

As used herein, the term “porous” refers to any porous material with a predominant pore distribution in the mesoporous, macroporous, or microporous ranges. The term “mesoporous” may refer to a porous material with a predominant pore distribution in the range from about 2 nm to 50 nm. Materials with a predominant pore distribution less than about 2 nm may be considered microporous, nanoporous, or having nanopores. Materials with a predominant pore distribution exceeding about 50 nm may be considered macroporous. Pore diameters, adsorption pore volume, and surface area may be determined by one of ordinary skill in the art using Brunauer-Emmett-Teller (BET) adsorption from N₂ adsorption isotherms at −169° C. with a Quantachrome autosorb automated gas sorption system.

As used herein, “density” may be applicable to either the density of a given material or to a density of pores in the material. As will be appreciated by one of ordinary skill in the art, the density of a material may be defined by its mass per unit volume. The density of a material may be proportional to a given refractive index. Therefore, a material with a higher degree a densification or densified (e.g., a higher density) provides for a higher refractive index. The density of pores, on the other hand, may relate to the concentration of pores in the material, for example. The density of pores is inversely proportional to a given refractive index depending on the content of the pores. For example, in the case of air filling the pores, a higher density of pores would provide for a lower index of refraction.

The porous materials of the present invention may have a predominant pore distribution ranging from about 1 nm to about 500 nm. For example, the pore size may be less than about 400 nm (e.g., about 50-400 nm, which includes a macroporous distribution), less than about 50 nm (e.g., about 20-50 nm, which includes a mesoporous distribution), less than about 20 nm (e.g., about 5-20 nm), or less than about 10 nm (e.g., about 5-8 nm). In one embodiment, the porous materials of the present invention may have a predominant pore distribution in the mesoporous range (e.g., about 2 nm to about 50 nm). Although the pore sizes may be completely random, it is also possible that the porous structure may have a specific distribution, such as a multi-modal (e.g., bimodal) distribution. For example, the porous structure may include a structured framework of both nanopores and mesopores or nanopores and macropores. In one embodiment, the light extraction layer may comprises pores ranging from about 2-10 nm, which may provide for the desired tuning of the index of refraction and/or for the desired light scattering.

The porous structure of the present invention may encompass either or both open cell and closed cell frameworks. Also, the pores may be of any suitable shape or dimension, such as spherical, cylindrical, slit-like, etc. For example, if the framework is open-celled, the pores may form channels or passageways connecting the pores. The porous structure may have any suitable porosity, density, or volume of open and/or closed cells. Additionally, the pores may be oriented in any suitable configuration, e.g., random, ordered, planar, etc.

As used herein and in the claims, the terms “comprising” and “including” are inclusive or open-ended and do not exclude additional unrecited elements, compositional components, or method steps. Accordingly, the terms “comprising” and “including” encompass the more restrictive terms “consisting essentially of” and “consisting o£” Additionally, all values provided herein include up to and including the endpoints given.

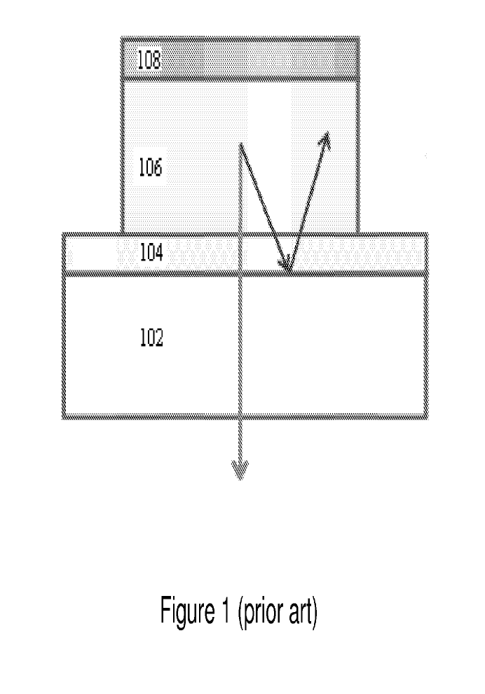

For purposes of comparison to embodiments of the present invention, FIG. 1 depicts a light-emitting device according to the prior art. The light-emitting device includes an OLED stack 106 (containing at least an emitter or organic layer described in more detail herein) supported by transparent substrate 102. The device also includes electrodes 104 and 108 with the OLED stack 106 positioned therebetween. Electrode 104 is desirably transparent (referred to herein as transparent electrode or transparent conducting oxide 104) and is positioned between substrate 102 and OLED stack 106.

During operation of the light-emitting device, light is generated and emitted isotropically from OLED stack 106 (containing an organic layer, for example) in a direction towards substrate 102. Typically, substrate 102 has a first refractive index (n₁) whereas TCO 104 has a second refractive index (n₂) that is typically different from n₁. For example, n₁ is typically between about 1.45 and about 1.55 and n₂ is typically between about 1.80 and about 2.00. As known to the skilled person, because refractive indices n₁ and n₂ may be different, a portion of light emitted by OLED stack 106 may be reflected back into TCO 104, rather than being transmitted into substrate 102.

Light that is not reflected by an interface between TCO 104 and substrate 102 is transmitted through substrate 102 and out of the light-emitting device (see arrows in FIG. 1 depicting the transmitted light and reflected light). As is shown in FIG. 1, however, some or a large percentage of the light is reflected back into the device. Thus, usable light emitted from the substrate surface may equate to only approximately 20% of the total emitted light. The loss of usable light may be related to a number of factors including, for example, the total internal reflection at interfaces of differing indices of refraction; losses at the reflective electrode due to absorption by the surface plasmon polariton; and light trapped (waveguided) inside the substrate. Thus, a major proportion of the light generated by the device never escapes the device.

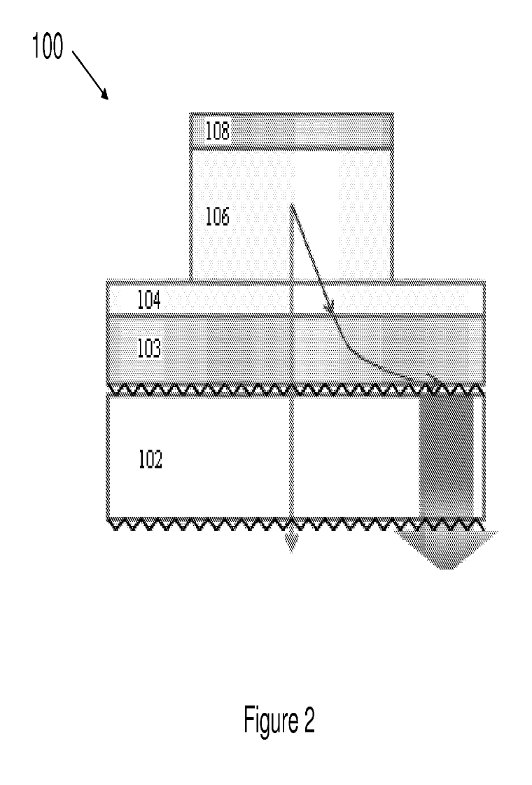

The present invention provides for at least one light extraction layer, which extracts this trapped light improving the overall light output of the device. In particular, the internal light extraction layer(s) includes a porous metal or metalloid oxide, which is provided between two adjacent layers in the device (see arrows in FIG. 2 depicting the transmitted light and re-concentrated light that leaves the device). According to one embodiment of the present invention depicted in FIG. 2, a light-emitting device 100 includes a substrate 102; a transparent conducting oxide 104; and at least one light extraction layer 103 comprising a porous metal or metalloid oxide, where the light extraction layer(s) 103 is disposed between the substrate 102 and the transparent conducting oxide 104.

The porous metal or metalloid oxide light extraction layer is an internal light extraction layer because it is positioned internally between the interface of two layers of the light-emitting device. In an exemplary embodiment, the at least one light extraction layer is positioned or sandwiched between the TCO and substrate interface. It is envisioned, however, that the same or different internal light extraction layers (e.g., the same or different materials and/or the same or different pores) may also be positioned at other interfaces in the light-emitting device. It is also possible that an external light extraction layer or layers may also be positioned on the outer surface of the substrate (i.e., not positioned between two layers).

The at least one light extraction layer includes a porous metal oxide or a porous metalloid oxide. The metal or metalloid oxide comprising the light extraction layer(s) may be any suitable metal or metalloid oxide (such as a transition metal oxide) known to one skilled in the art. For example, suitable metal or metalloid oxides may include any metal or metalloid oxide that can be made via a sol gel or is aero-gel process. A suitable metal or metalloid oxide may also be selected based on, but not limited to, the material of the substrate, the material of the TCO, the material(s) of the OLED stack and organic layer, the desired wavelength range for the emitted light, performance factors of the device, such as efficiency or light output, and/or a desired cost. For example, the light extraction layer(s) may include one or more oxides of metals or metalloids, such as titanium, silicon, tin, germanium, aluminum, zirconium, zinc, indium, cadmium, hafnium, tungsten, vanadium, chromium, molybdenum, iridium, nickel, lanthanum, niobium, calcium, strontium, and tantalum. Mixed metal or metalloid oxides, containing two or more different metals, may also be useful. In an exemplary embodiment, the metal or metalloid oxide comprises titania (e.g., TiO₂), silica (e.g., SiO₂), zinc oxide (e.g., ZnO), aluminum oxide, zirconium oxide, lanthanum oxide, niobium oxide, tungsten oxide, tin oxide, indium oxide, indium tin oxide (ITO), strontium oxide, vanadium oxide, molybdenum oxide, calcium/titanium oxide, or blends of two or more such materials. In another embodiment, the light extraction layer(s) comprises titania.

The light extraction layer(s) may be tuned to provide an index of refraction and light scattering using one or several different parameters including, but not limited to: (i) changing the pore size, porosity, pore density, or pore orientation or structure; (ii) compositional doping, (iii) adding an insulating, conducting, or semiconducting component, (iv) filling the pores, for example, with low or high index materials; vi) changing the thickness or number of layers, or combinations thereof.

For example, the light extraction layer(s) may be tuned by including a compositional dopant and/or by adding an insulating, conducting, or semiconducting inorganic or organic component to optimize chemical and physical properties. In one embodiment of the present invention, the porous metal or metalloid oxide comprises a dopant. Any suitable dopant may be selected for the metal or metalloid oxide by one of ordinary skill in the art. For example, the dopant may include, but is not limited to, Al, B, Tl, In, Ga, Ce, Co, Fe, Mn, N, Nd, Pd, Pt, S, V, W, Eu, Cr, Tb, Er, Pr, and combinations thereof. In another embodiment of the present invention, the at least one light extraction layer includes a suitable semiconducting material, such as germanium or silicon. The amount of dopant and/or insulating, conducting, or semiconducting component can be controlled by one of ordinary skill in the art as desired.

The light extraction layer may be a single layer or may be formed from one or more sub-layers (multilayer) or a gradient thereof. For example, a number of metal or metalloid oxides or combinations thereof may be formed into a number of sub-layers in order to produce the at least one light extraction layer. In one embodiment, the light extraction layer comprises two layers (e.g., dual layer). The light extraction layers may be the same or different. The sub-layers could differ with respect to material, pore size, porosity, pore orientation, degree of doping, refractive index, or other variable. Thus, the light extraction layer may comprise more than one porous metal or metalloid oxide layer.

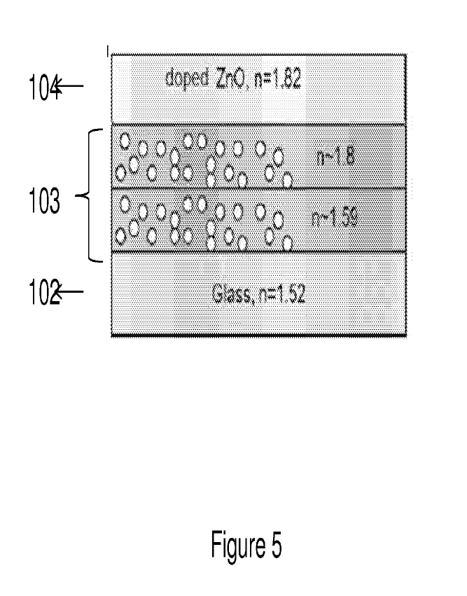

FIG. 5 depicts one embodiment of a light-emitting device having more than one light extraction layer, namely, two light extraction layers, where each layer has a different pore size and pore density, which results in different indices of refraction. For example, the first light extraction layer 103 has an index of refraction of about 1.8. The second light extraction layer 103 has an index of refraction of about 1.59. Thus, the refractive index is approximately matched in the light extraction layers 103 to the respective TCO layer 104 and glass substrate layer 102, and the light scattering may also be optimized, for example.

Alternatively, light scattering may be optimized by densification of the light extraction layers 103 at the interfaces between each of the layers and/or the interface between the light extraction layers 103 and the TCO layer 104 and/or glass substrate layer 102. The densification may occur by penetration of a layer precursor followed by crystallization or by sintering of the porous material, as may be appreciated by one of ordinary skill in the art. The density of the porous layer correlates to the refractive index, such that an increase in density leads to a higher refractive index. Having three or more regions of different refractive indices, for instance in the arrangement high low high, can result in a bandpass filter, which are known to one of ordinary skill in the art. In general, these band pass filters affect specific regions of the visible light. The thicknesses of the layers with different refractive indices determine the wavelength that is passed through the filter. However, the results indicate that this system has an improvement across the visible spectra. The presence of a range of bandpass filters due to a range of high low high layer thicknesses over lateral distances on the order of the wavelength of light provides a range of bandpass filter wavelengths encompassing the entire visible regime.

In one embodiment of the invention, at least one light extraction layer is densified at a region adjacent an interface with another layer. In other words, the density of this region of the light extraction layer is increased, which also provides for a higher index of refraction, in that portion of the light extraction layer. As one example, the densified region comprises a refractive index higher than a remainder of the at least one light extraction layer, which has a lower refractive index. The densification may occur at a region of interface between two light extraction layers. The densification may also occur at a region of interface between a light extraction layer and the substrate. The bands of densification may provide for a high/low/high refractive index effect (e.g., bandpass filter). For example, in the case with two light extraction layers, the first light extraction layer may be densified adjacent the substrate and the second light extraction layer may be densified adjacent the first light extraction layer. This provides for a high refractive index adjacent the substrate, a low refractive index in the remainder of the first light extraction layer, a high refractive index at the interface between the first and second light extraction layers, and a low refractive index in the remainder of the second light extraction layer.

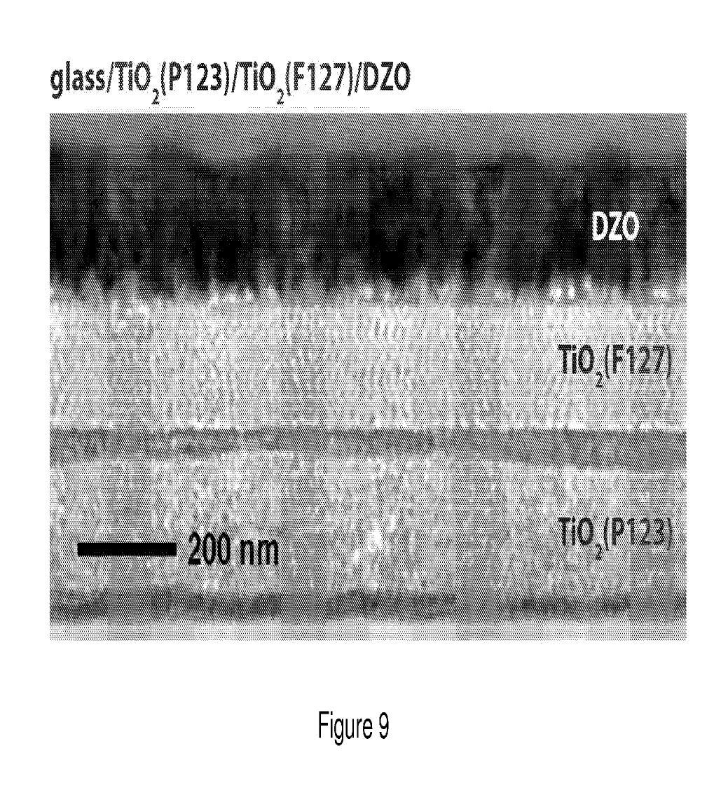

FIG. 9 depicts an embodiment of the invention including two light extraction and densified regions therein. The two light extraction layers include TiO₂ between a glass layer and a doped zinc oxide (DZO) layer. TiO₂ (F127) designates a mesoporous TiO₂ obtained from a Pluronic® F127 block copolymer templating agent and TiO₂ (P123) designates a mesoporous TiO₂ obtained from a Pluronic® P123 block copolymer templating agent. In FIG. 9, a densification (darker area) can be observed at the interface between the TiO₂ (F127) and TiO₂ (P123) light extraction layers. A densification (darker area) can also be observed at the interface between the TiO₂ (P123) and the glass substrate. It will be appreciated by one of ordinary skill in the art of electron microscopy that the darker region corresponds to higher material density compared to the lighter region in an electron micrograph. In FIG. 9, the denser region has thickness variation of 20 nm to 50 nm over a distance of 200-500 mu, consistent with the thickness variation required for an optical filter and a distance consistent with a lens. Vertical striations are also observed throughout the film that is may collectively act as a macro lens, which would be well understood by one of ordinary skill in the art.

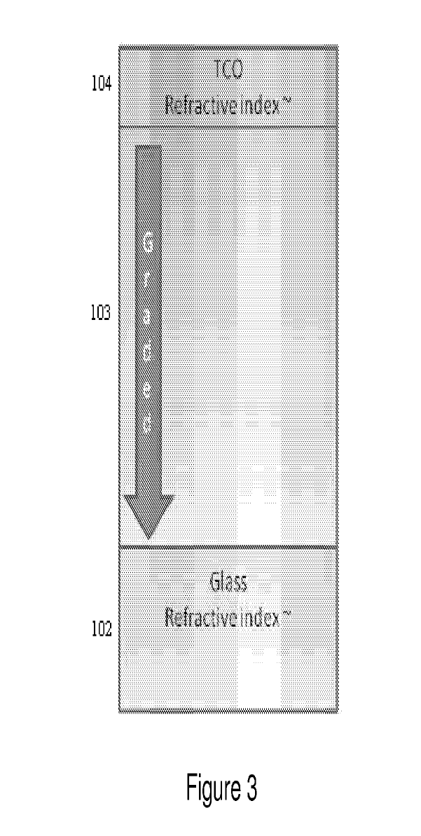

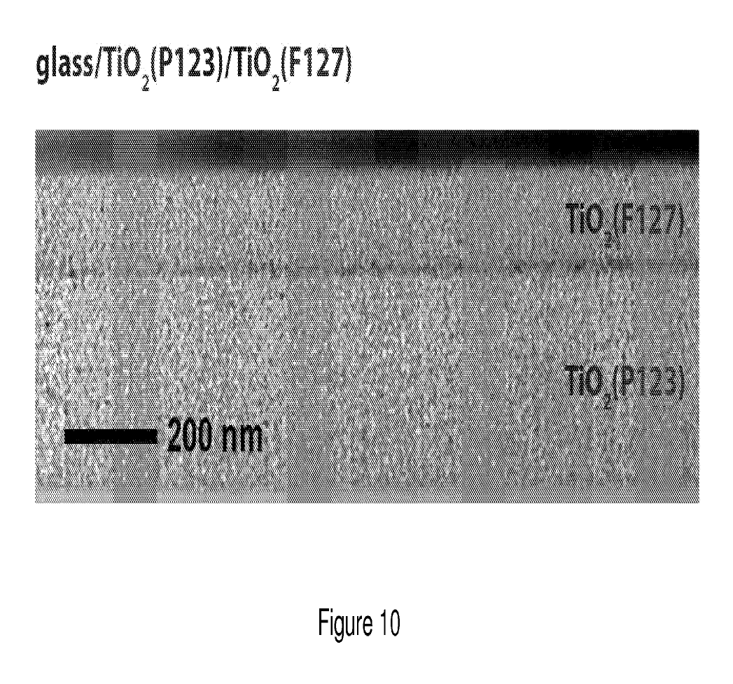

FIG. 10 shows an embodiment of the invention including two light extraction layers comprising TiO₂ on a glass layer with only a minor densification area between the TiO₂ (F127) and TiO₂ (P123) light extraction layers and no or minor densification between the TiO₂ (P123) and the glass substrate. This type of device may comprise a gradient, for example, as depicted in FIG. 3. Additionally, an external light extraction layer may be provided to further extract light from the device.

Although the thickness of the light extraction layer is not particularly limited, the light extraction layer(s) may range between about 50 nm and about 1000 nm in total thickness. The thickness may also be varied, as needed, to tune the properties (e.g., refractive index) of the light extraction layer(s).

The porous metal or metalloid oxide may have any suitable structure as would be well known to one skilled in the art. For example, the metal or metalloid oxide may be crystalline (e.g., anatase, brookite, or rutile), partly crystalline, or amorphous. In an exemplary embodiment, the metal or metalloid oxide is in highly crystalline form.

The pores in the porous metal or metalloid oxide are not especially limited, but are preferably formed to provide the desired refractive index and/or light scattering. The porous structure including the pore distribution, pore size, porosity, density, pore volume, pore orientation, etc., may be tuned or varied depending on the porous metal or metalloid oxide properties desired (e.g., refractive index and light scattering). For example, films of similar thickness but with a higher pore density may exhibit a lower refractive index.

The porous materials of the present invention may have any suitable pore distribution. In an exemplary embodiment, the predominant pore distribution of the porous metal oxides ranges from about 2 nm to about 500 nm.

Thus, the pore sizes may be completely random. The pore size may also be tuned to have a certain distribution (e.g., a uni-modal, bimodal, or multi-modal distribution). In an exemplary embodiment, the porous structure includes a structured framework having both nanopores (e.g., on the order of about 2 nm to about 8 nm diameter) and mesopores and/or macropores (e.g., on the order of about 20 nm to about 200 nm diameter, or more particularly about 20 nm to about 50 nm). The porous structure of the present invention may encompass either or both open cell and closed cell frameworks. Also, the pores may be of any suitable shape or dimension, such as spherical, cylindrical, slit-like, etc. Additionally, the pores may be oriented in any suitable configuration, e.g., random, ordered, planar, etc.

The porous structure may be tuned to form at least one light extraction layer having a single refractive index or a refractive index that varies over the thickness of the layer(s). For example, the layer or sublayers may have a stepped index or a gradient change of refractive index. As shown in FIG. 3, the light extraction layer(s) 103 may be graded to change over the thickness of the layer. For example, the light extraction layer(s) 103 may change along a gradient such that the refractive index is identical to or closely matches the refractive index adjacent to the TCO layer 104 and also is identical to or closely matches the refractive index adjacent to the substrate 102 (e.g., glass). The use of such a graded refractive index can reduce or eliminate a reflecting interface due to the close matching of refractive indices of adjacent layers, which prevents internal reflection of light and reduces light trapped inside the interfaces of traditional light-emitting structures. To achieve this effect, for example, the porous metal or metalloid oxide may contain smaller pores (e.g., a higher refractive index, such as about 1.8 to 2.0) near or proximate to the TCO 104 which slowly transition into larger pores (e.g., a lower refractive index, such as about 1.5) near or proximate to the substrate 102. Alternatively, or in addition, the density of the pores can be controlled to achieve the desired gradient or refractive index matching. In a preferred embodiment, each adjacent sublayer of the porous metal or metalloid oxide structure will have similar refractive indices to avoid having an interface between layers with a large disparity in refractive index.

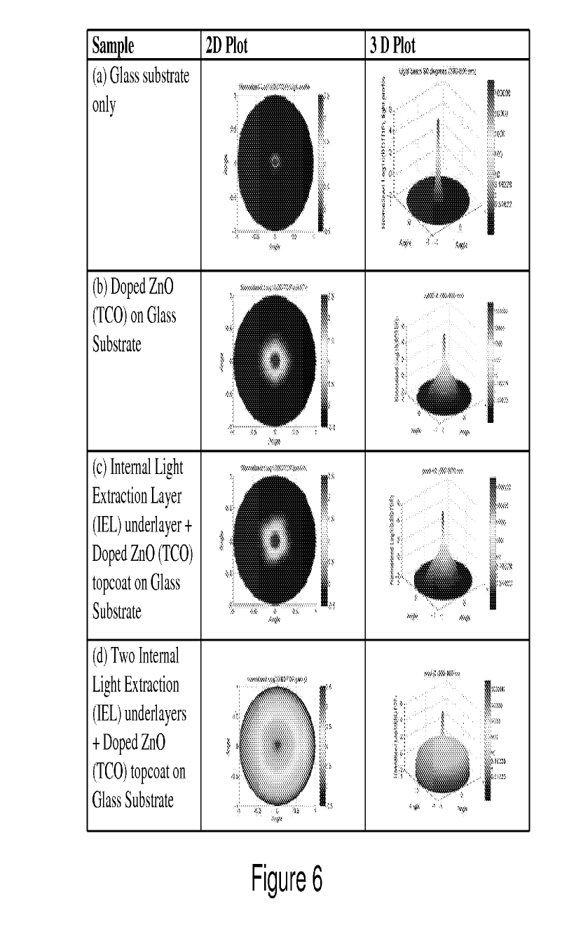

The porous structure may be tuned to provide light scattering. FIG. 6 depicts goniometry measurements for examples of normalized light scattering for 90 degree incidence showing 2D and 3D images. Example (a) shows a comparative example for a glass substrate only. As is evident from the mostly black area, there is minimal light scattering (i.e., no dispersion of light). Example (b) shows a comparative example with a transparent conducting material (doped zinc oxide) on a glass substrate. The light center ring (2D) and widened cone (3D) indicates there is some degree of light scattering. Similarly, Example (c) shows an internal light extract layer in accordance with the invention positioned between a transparent conducting material (doped zinc oxide) and a glass substrate. The center ring (2D) and widened cone (3D) indicates some light scattering. Example (d) shows two internal light extraction layers in accordance with the invention positioned between a transparent conducting material (doped zinc oxide) and a glass substrate. The mostly light center ring (2D) and broadened cone (3D) establish a great amount of light scattering (i.e., good dispersion of light).

The pores may contain or be filled, partially or completely, with any suitable fluid or material (such as low refractive index materials). For example, the pores may contain air, nitrogen, or another suitable fluid. The fluid may be gaseous and/or liquid. Alternatively or additionally, the pores may contain a metal or metalloid, or oxide thereof (including the metal or metalloid oxide material of the TCO). Preferably, the pores are filled with a fluid or material that can withstand temperatures up to 500° C. (which are the temperatures typically encountered in a chemical vapor deposition process). The refractive index of the light extraction layer(s) may also be tuned by filling the pores with different materials or fluids throughout the thickness of the layer or as a gradient over the layer. For example, the pores may contain the same TCO material up through about 50% of the layer and the remaining portion of the pores may be filled with air. FIG. 3 depicts a changing gradient of the light extraction layer 103, which may also be attributable to having different materials/fluids in the pores.

The porous metal or metalloid oxide of the light extraction layer(s) may have a given index of refraction (n₃) or a hybrid index of refraction (e.g., varying throughout the layer). For example, the porous metal or metalloid oxide may include at least one metal or metalloid oxide having a first refractive index (n₄) and pores having a second refractive index (n₅). The metal or metalloid oxide would typically have the higher index of refraction and the pores would typically have the lower index of refraction. In an exemplary embodiment, there is some difference or delta (A) between the refractive index (n₄) of the metal or metalloid oxide and the refractive index (n₅) of the pores. The delta may also be tuned to achieve the desired properties of the light extraction layer(s). For example, the difference between the first refractive index of the at least one metal or metalloid oxide and the second refractive index of the pores may be 0.5 or greater, 1 or greater, 1.5 or greater, or 2 or greater. In certain embodiments, the delta may be as large as possible. For example, the porous metal or metalloid oxide may be a material with a very high index of refraction (such as titania having a refractive index of about 2.4-2.9 depending on the phase), and the pores may be filled with a substance having a very low index of refraction (such as air having a refractive index of about 1). In some embodiments of the present invention where the at least one light extraction layer has a gradient of refractive indexes, a higher refractive index (e.g., 1.7-1.8) is adjacent to the transparent conducting material and a lower refractive index (e.g., 1.5-1.6) is adjacent to the substrate.

In an exemplary embodiment, the light-emitting device includes a substrate; a transparent conducting oxide (TCO); and at least one mesoporous light extraction layer (MEL) containing mesoporous titania, where the MEL is deposited between the substrate and the transparent conducting oxide.

The porous metal or metalloid oxide and the light extraction layer(s) may be prepared by any suitable method. For instance, the techniques described in “Effects of Template and Precursor Chemistry on Structure and Properties of Mesoporous TiO₂ Thin Films,” by X. Shari Li et al., Langmuir 2004, 20, 9095-9102 or “Synthesis and Li-Ion Insertion Properties of Highly Crystalline Mesoporous Rutile TiO₂,” by Donghai Wang et al., Chem. Mater. 2008, 20, 3435-3442, both incorporated herein by reference in their entirety for all purposes, may be suitable. For example, highly crystalline porous metal or metalloid oxides (e.g., mesoporous transition metal oxides) may be formed by stimulating controlled nucleation of the desired crystalline phases. The synthesis route may start from a metal salt precursor, which hydrolyzes into metal oxyclusters. The clusters self-assemble with functional surfactants into mesostructures and the metal oxyclusters further condense and nucleate with the surfactant functional group and grow into nanocrystals. In one embodiment, hierarchical mesoporous metal oxides (such as titania) may be fabricated by incorporating a sacrificial material (such as silica or polymer beads, e.g., on the order of about 20 nm to about 200 nm) during the synthesis of the highly crystalline mesoporous metal oxide. The resulting structure may have, for example, 2 nm to 5 nm diameter nanopores (depending upon the surfactant template used to form the pores) and 20 nm to 200 nm diameter mesopores from the sacrificial porogens.

In one embodiment, the porous metal oxide may be formed from a metal alkoxide using sal gel or aero-gel techniques. For example, the sol gel process may use surfactant templates, such as block copolymer, or hard polymer templates, which when burned off in the annealing process, produce pores. It has been found that the selection of certain parameters, such as type of template, concentration of the template, molecular weight ratios of components within the template when the template is a diblock copolymer, and annealing conditions, during formation of the porous metal or metalloid oxide can allow for tuning of the refractive index and light scattering. In particular, the selection of a type of surfactant template from a non-ionic, ionic, or amphiphilic block copolymer may result in desired refractive index and light scattering. In an exemplary embodiment, the surfactant template comprises an amphiphilic tri-block copolymer, such as a poly(propylene oxide) segment capped by polyethylene oxide) segments on each end. Amphiphilic tri-block copolymers, such as Pluronic® polymers, include a hydrophobic poly(propylene oxide) B segment capped by hydrophilic poly(ethylene oxide) A segments on each end (PEOxPPOyPEOx). The concentration of the amount of template surfactant may allow for tuning of the refractive index and light scattering. The selection of the molecular weight/chain length of the two components, PEO and PPO, may also be modified to result in different refractive index and light scattering results. For example, Pluronic® F127 block copolymer (PEO₁₀₀PPO₆₅PEO₁₀₀, Mn=12,600) and Pluronic® P123 block copolymer (PEO₂₁PPO₆₅PEO₂₁, Mn=5,750) may be used as templating agents to obtain a desired mesoporous metal oxide, such as TiO₂.

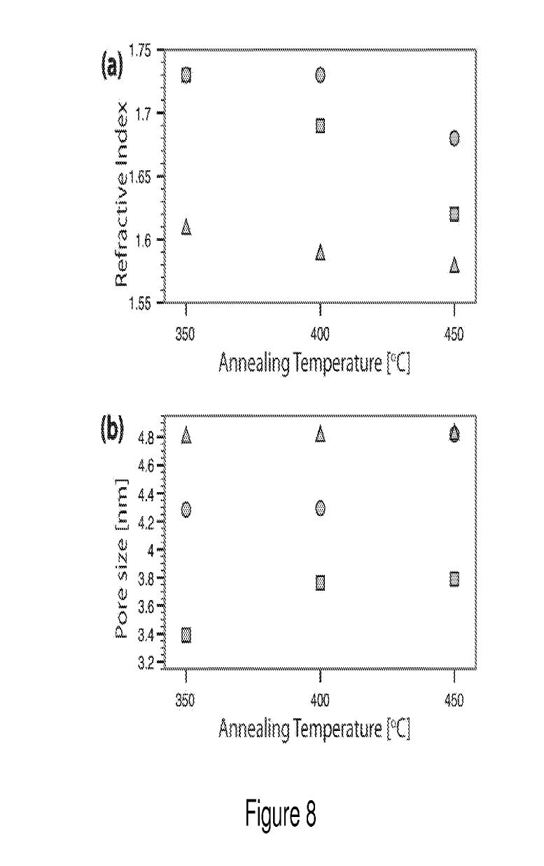

Additionally, the selection of the annealing conditions (e.g., heating to about 300-500° C.) may also allow for tuning of the refractive index and/or light scattering. FIG. 8 shows (a) refractive indices (mesoporous TiO₂ films on Si substrates) and (b) pore sizes (mesoporous TiO₂ bulk material) for TiO₂-F127 (□), TiO₂-P123 (O), and TiO₂-2xP123 (Δ), which are plotted versus the annealing temperature of the material at 350° C., 400° C., and 450° C., respectively. Exemplary results may be found, for example, by annealing the porous metal oxide layer more than once (e.g., twice) at the same or varying temperatures. For example, the annealing may provide for pore sizes that range from 3-5 nm to tune the refractive index (e.g., about 1.5-1.8) and from is about 20-50 nm to tune the light scattering (see FIG. 6(d)).

The light emitting device 100 includes a transparent conducting material (TCM), preferably a TCM layer 104. A subset of TCMs are transparent conducting oxides (TCO) that typically function as an anode in light-emitting devices (e.g., OLEDs). The TCO may be formed from any suitable TCO, for example, indium tin oxide, indium zinc oxide, fluorine-doped tin oxide, and niobium-doped titanium dioxide. In an exemplary embodiment, the TCM comprises doped zinc oxide, indium tin oxide, indium zinc oxide, fluorine-doped tin oxide, niobium-doped titanium dioxide, graphene, carbon nanotubes, or silver. In a preferred embodiment, the TCO is an indium free coating, such as a doped zinc oxide coating as described in U.S. Pat. Nos. 7,740,901 and 7,732,012, herein incorporated by reference in their entirety for all purposes.

The light emitting device 100 includes a substrate 102. Substrate 102 may be formed of any suitable transparent material (e.g., having greater than 80% transmission) for transmitting light at a desired wavelength range. Materials for substrate 102 may include, but are not limited to, glass, polymer substrates or films, and plastics that are consistent with the high temperature processing. Suitable glass substrates may include, for example, soda lime glass including soda lime float glass and low-iron soda lime glass; borosilicate glass; and flat panel display glass. Suitable polymer substrates may have a higher Tₘ melting point of greater than 350° C., for example, polyaryletheretherketone (PEEK), polyetherketoneketone (PEKK), polyamides, polyimides, polycarbonates and the like. The substrate may be in any suitable form (e.g., sheet, a film, a composite, or the like), and of any suitable thickness (e.g., less than about 15 mils (thousandths of an inch)). The substrate could be a single layer, or could itself contain multiple layers.

Other components may also be added to or incorporated into layers of the light-emitting device. For example, fillers, stabilizers, colorants, etc. may be added to and incorporated with a layer (e.g., a polymer substrate) or applied to a surface (e.g., of the substrate) based on the properties desired.

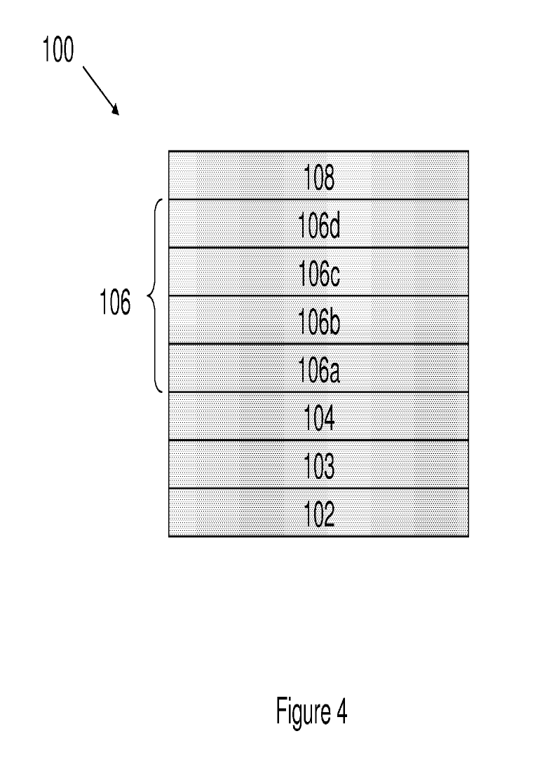

The light emitting device may contain additional components, which may or may not be described herein, as would be readily recognized by one of ordinary skill in the art. For example, an organic light emitting diode (OLED) may also contain an OLED stack and a cathode as depicted in FIG. 4. The OLED stack may contain a light emissive layer or an emitter layer 106c containing an organic material, a hole transport layer 106b, a hole injection layer 106a, and an electronic transport layer 106d. The light emitting device 100 may include an electrode 108, which typically functions as a cathode in light-emitting devices (e.g., OLEDs). The cathode 108 may be formed from any suitable conductive metal material, such as, but not limited to, aluminum, copper, silver, magnesium, or calcium. The cathode 108 may optionally comprise a reflective surface (e.g., a mirror) to reflect the light back into the device and through the light extraction layer(s).

When an appropriate voltage is applied to emitter layer 106c, the injected positive and negative charges recombine in the emissive layer to produce light. The emissive layer may include, but is not limited to, blue, red and/or green light emitting organic materials. The structure of emitter layer 106c and type of electrodes 104, 108 are desirably selected to maximize the recombination process in the emissive layer, thus maximizing the light output from light-emitting device 100. In general, emitter layer 106e may be formed with any suitable organic material. For example, materials for emitter layer 106c may include, but are not limited to, polymers, small molecules and oligomers.

The specialized internal light extraction layer(s) described herein have been found to provide improved properties over other light extraction techniques. In particular, the at least one porous metal or metalloid oxide light extraction layer has been found to be particularly effective in organic light emitting diodes (OLEDs). In particular, by tuning the refractive index or indices of materials along with the degree of light scattering based on the pore size, filling the pores, doping, adding semiconducting components, etc., the light output of white OLEDs may be improved to without affecting the operating voltage. Thus, the power efficiency of the OLEDs utilizing the light extraction layer(s) described herein is greatly improved. For example, the light extraction layer(s) may improve the external quantum efficiency (EQE) (e.g., the amount of light emitted from the device) of the OLED over the entire visible light range of about 400 nm to about 800 nm (as opposed to over a limited range of wavelengths). Thus, the external quantum efficiency may be improved for white OLEDs over a broad wavelength range.

According to another embodiment of the present invention, a method for forming a light-emitting device includes forming at least one light extraction layer comprising a porous metal or metalloid oxide on a substrate; and forming a transparent conducting material on the light extraction layer(s).

The porous metal or metalloid oxide may be formed by any suitable technique known in the art as described in more detail above. Moreover, at least one index of refraction and light scattering of the light extraction layer(s) may be tuned by at least one of the following: changing the pore size; pore density; compositional doping; adding an insulating, conducting or semiconducting component; filling the pores, thickness of the layer, template selection (e.g., type and concentration), and/or annealing conditions, etc., as previously discussed.

According to one embodiment of the present invention, a method of providing a light extraction layer in a light-emitting device comprises varying at least one of pore size and pore density of a porous metal or metalloid oxide to obtain at least one refractive index and light scattering for at least one light extraction layer comprising the porous metal or metalloid oxide, wherein the at least one light extraction layer is positioned between a substrate and a transparent conducting oxide.

The porous metal or metalloid oxide may be deposited on or applied to a substrate to form the light extraction layer(s). The layer or layers may be applied substantially uniformly over the entire substrate or a portion thereof. The layer(s) may be applied using any suitable equipment and techniques known in the art. For example, the light extraction layer(s) may be formed by solution processing, atmospheric pressure chemical vapor deposition (APCVD), ultraviolet-assisted chemical vapor deposition (UVCVD), plasma-assisted or enhanced chemical vapor deposition (PACVD or PECVD), atomic layer deposition (ALD), physical vapor deposition (PVD), vacuum thermal evaporation, a sputtering process, or by a pulsed laser deposition (PLD) process. In an exemplary embodiment, the light extraction layer(s) may be formed on the substrate using a chemical vapor deposition (CVD) process, which is performed at atmospheric pressure and at a temperature of less than about 450° C., and in some embodiments, less than about 400° C. According to another embodiment, the CVD process may be performed at atmospheric pressure and a temperature of from about 300° C. to about 650° C. In some embodiments, it is desired to keep process temperatures at less than about 400° C. so that the materials described herein are stable during manufacture. Any suitable temperatures may be selected by one skilled in the art based on the materials and method selected for attaching the light extraction layer(s) to the substrate.

The light extraction layer(s) may be formed to any suitable thickness. For example, the total thickness of the light extraction layer(s) may range from about 2 nm to about 500 nm. If a thicker layer is required, it is envisioned that additional layers may be applied on the substrate until the desired thickness is achieved. The additional layers may be the same or different compositions, e.g., containing different metal oxides, pore structures, etc.

The TCO may be deposited on or applied to the light extraction layer(s). The TCO layer may also be applied using any suitable equipment and techniques known in the art. For example, the techniques and conditions specified in U.S. Pat. Nos. 7,740,901 and 7,732,012, herein incorporated by reference in their entirety for all purposes, are particularly suitable. In an exemplary embodiment, the transparent electrode is also formed by a CVD process at the exemplary conditions specified above for the light extraction layer. The TCO material may penetrate into the pores of the porous metal or metalloid oxide at this time, for example. Depending on the properties of the porous metal or metalloid oxide, the TCO material may penetrate a given volume percent or a certain thickness of the light extraction layer. The TCO may also not penetrate the pores of the porous metal oxide, if the pores are closed, the pores are already filled with another material, or a barrier prevents penetration of the TCO, for example.

The method for forming the light-emitting device may also include forming at least one layer including any typical layers used in a light-emitting device, such as an OLED, including but not limited to, an emitter layer or organic layer, a hole transport layer, a hole injection layer, and an electronic transport layer. Each of these layers may be formed using any suitable methods and equipment known in the industry. For example, the organic layer may be formed on the TCO. The organic layer may be formed, by any suitable process, for example, by depositing a hole injection layer on the TCO, depositing a hole transport layer on the hole injection layer, depositing a light emissive layer on the hole transport layer, and depositing an electron transport layer on the light emissive layer. As one example, the emitter layer may be formed by a vacuum evaporation process. The electrode layer may then be formed on the OLED stack. For example, the electrode (cathode) is formed on the electron transport layer on the organic layer. The electrode may also be formed by any suitable process, for example, by a vacuum evaporation process or by a PVD process, such as sputtering.

It is also envisioned that additional internal light extraction layers may be positioned in the light-emitting device, if desired. In particular, an internal light extraction layer comprising a porous metal or metalloid oxide may be positioned between any two adjacent layers in an OLED device. The light extraction layer(s) may be applied using any suitable techniques described herein or known in the art. Preferably, the at least one internal light extraction layer is added between at least one of the transparent conducting oxide (TCO)-substrate interface or the TCO-organic interface if conductive enough to facilitate charge injection into the next layer.

Although the order of assembling the light-emitting device is described in a certain order, it is also recognized that the forming or applying steps may occur or be conducted in any suitable order. Furthermore, it is desirable that each of the layers in the light-emitting device exhibit good durability and stability. In particular, the layers should preferably demonstrate good adhesion with no delamination.

### EXAMPLES

Unless noted otherwise, all experiments were carried out under ambient conditions in air.

TiO₂ Sol-Gel Synthesis

Two types of templating Pluronic® block copolymers, based on ethylene oxide and propylene oxide, were used in the TiO₂ sol-gel synthesis. Pluronic® F127 block copolymer, (755 mg, 0.06 mmol) or Pluronic® P123 block copolymer (690 mg, 0.12 mmol or 345 mg, 0.06 mmol), each difunetional block copolymers terminating in primary hydroxyl groups, was dissolved in 7.41 ml n-butanol. Pluronic® P123 block copolymer, at both concentrations, dissolved completely, but Pluronic® F127 block copolymer yielded a slightly opaque colloidal solution. Separately, 1.33 ml (16.1 mmol concentration) of HCl was slowly added to 1.93 ml (9.2 mmol) titanium tetraethoxide, Ti(OEt)₄, under vigorous stirring to mitigate any temperature increase from the exothermic reaction. The respective polymer solutions were then slowly pipetted into the Ti(OEt)₄/HCl solution at room temperature over the course of 2-3 min while stirring. The final sol-gel solutions had an overall Ti(OEt)₄/HCl/polymer/n-BuOH ratio of 1:1.75:0.013:8.8 and 1:1.75:0.0065:8.8, respectively. All sol-gel solutions were clear; the originally colloidal Pluronic® F127 block copolymer suspension dissolved upon contact with the more polar, aqueous Ti(OEt)₄/HCl solution.

The sol-gel materials and the resulting TiO₂ materials after annealing are denoted as follows herein: TiO₂-F127 (prepared from a sol-gel solution containing 0.06 mmol Pluronic® F127 block copolymer), TiO₂-P123 (prepared from sol-gel solution containing 0.06 mmol Pluronic® P123 block copolymer), and TiO₂-2xP123 (prepared from sol-gel solution containing 0.12 mmol Pluronic® P123 block copolymer).

Bulk material for BET measurements was prepared by spreading sol-gel solution onto microscope glass slides. The material was allowed to cure in air at room temperature for ≧48 h. Then, the coated glass slides were transferred into a muffle furnace and heated to the desired temperature at a rate of 1° C./min and held for 4 h at a maximum temperature of 350° C., 400° C. or 450° C., respectively. At the end of the heating period, the samples were allowed to cool down to 50° C. as fast as possible without opening the furnace (over the course of several hours). The solid material was removed from the microscope glass slides and crushed into a homogeneous powder prior to XRD and BET analysis. With increasing annealing temperatures, the color of the bulk TiO₂ material changed from dark brown to light beige, which indicated that not all organic matter was burnt out of the thicker films (compared to the spincoated films) at the 350° C.

Thin Film Preparation

Si substrates (1 cm×1 cm; <100>) were cleaned with organic solvents in a sequence of hot trichloroethylene, acetone, and isopropanol. Following treatment with UV ozone (UVO-Cleaner, Jelight Co. Inc, at 15 mW/cm² for 20 min), the substrates were hydroxylated by dipping them into NH₄OH solution (30.0% NH₃ basis) for 1 min and subsequent rinsing in deionized (DI) water. After blow-drying in air, a thin film of TiO₂ sal-gel solution was spin coated onto the substrates from 86 μl Ti(OEt)₄/HCl/polymer/n-BuOH solution (2400 rpm, 40 s). The samples were allowed to cure at room temperature for ≧48 h and subsequently transferred into a muffle furnace. The samples were then heated to the desired temperature at a rate of 1° C./min and held for 4 h at a maximum temperature of 350° C., 400° C. or 450° C., respectively. At the end of the heating period, the samples were allowed to cool down to 50° C. as fast as possible without opening the furnace (over the course of several hours).

Analysis and Instrumentation

Powder X-ray diffraction (XRD) studies of finely ground bulk samples were conducted using a Rigaku Miniflex II powder diffractometer with monochromatic Cu Kα radiation (λ=1.54059 Å) and Bragg-Brentano geometry. Brunauer-Emmett-Teller (BET) surface area and pore size of the bulk powder samples were determined through nitrogen adsorption isotherms at −169° C. with a Quantachrome autosorb automated gas sorption system. All samples were degassed at 100° C. for 24 h before analysis. Scanning electron microscopy (SEM), to study the surface topology of the films, was performed using a JEOL JSM-5900 microscope. Atomic Force Microscopy (AFM; DI Nanoscope IIIa Multimode) was employed to investigate the morphology of the spincoated films. AFM images were recorded at tapping mode with a silicon AFM tip. The experimental settings of all AFM images were: scan rate=1 Hz, scan resolution=512 lines, amplitude setpoint=1V, integral gain=0.2 and proportional gain=0.3.

The refractive index and thickness of the TiO₂-P123 and TiO₂-2xP123 films were measured by ellipsometry using a Spectoscopic Ellipsometer alpha-SE from J. A. Woolam Co., Inc. (CompleteEASE™ Version 3.65; HeNe laser, 632.8 nm; Model: Si with Transparent Film). The refractive index and thickness of the TiO₂-F127 films were determined using a Rudolf Auto EL-III ellipsometer (HeNe laser, 632.8 nm). Reflectance spectra of the TiO₂ films on Si substrates were recorded with a UV-Vis-NIR Spectrophotometer (Varian, Cary 5) in the wavelength range from 800-200 nm at a resolution of 0.5 nm or higher. Thermogravimetric Analysis (TGA) and Differential Scanning calorimetry (DSC) were performed on a DSC STA 449 Jupiter Netzsch instrument equipped with an Aelos QMS 403C MS. The powders were loaded in alumina crucibles and the data were obtained by heating the samples under air flow (25 ml/min) from room temperature to 550° C. at a rate of 5° C./min.

Macroscopic Thin Film Morphology

As evidenced by scanning electron microscopy (SEM) and atomic force microscopy (AFM) on the micron scale all TiO₂ thin films appear smooth and continuous, except for the TiO₂-2xP123 film annealed at 450° C. AFM measurements indicate that the roughness (Rₘₛ) of the mesoporous TiO₂-2xP123 film annealed at 350° C. is 0.3 nm, which is at or close to the resolution limit. It increases to 0.4 nm for the one annealed at 400° C.

Refractive Indices and Mesopores

Refractive index (n) measurements indicate that optical properties of mesoporous TiO₂ thin films can be tuned by adjusting the chemical composition of the initial sol-gel solution precursor. Refractive indices determined for the different spincoated films, as well as information on pore size, volume, and surface area of the bulk TiO₂ materials are listed in Table 1. As is evident, varying the type of templating surfactant and also the surfactant concentration influences the pore formation and the resulting refractive index of the mesoporous material.

TABLE 1
Refractive index of mesoporous TiO₂ films and BET data of bulk TiO₂
materials, all prepared by sol-gel synthesis using Pluronic ® F127
block copolymer and Pluronic ® P123 block copolymer fillers,
respectively, as templating agents.

| | Annealing | | | Pore | |
|---|---|---|---|---|---|
| | temperature | Refractive | Pore size | volume | Surface |
| Sample | [° C.] | index (n) | [nm] | [cm³/g] | area [m²/g] |
| TiO₂-F127 | 350 | 1.73 | 3.390 | 0.1445 | 121.962 |
| TiO₂-F127 | 400 | 1.69 | 3.763 | 0.3392 | 131.097 |
| TiO₂-F127 | 450 | 1.62 | 3.789 | 0.1329 | 133.246 |
| TiO₂-P123 | 350 | 1.73 | 4.283 | 0.0826 | 66.559 |
| TiO₂-P123 | 400 | 1.73 | 4.293 | 0.1643 | 106.256 |
| TiO₂-P123 | 450 | 1.68 | 4.818 | 0.1308 | 74.367 |
| TiO₂- | 350 | 1.61 | 4.815 | 0.2361 | 192.469 |
| 2xP123 | | | | | |
| TiO₂- | 400 | 1.59 | 4.824 | 0.1660 | 129.10 |
| 2xP123 | | | | | |
| TiO₂- | 450 | 1.58 | 4.837 | 0.3877 | 103.439 |
| 2xP123 | | | | | |

For the mesoporous TiO₂ films on Si substrates, a decrease in refractive index was detectable with increasing annealing temperature for the samples of all three sets of sol-gel composition. The ongoing hydrolysis and condensation reactions which affect the film density in the temperature range below ˜350° C. do not appear to be a main factor influencing the refractive indices, which have been annealed at higher temperatures. Thermogravimetric analysis (TGA) shows that the weight of TiO₂-F127 and TiO₂-P123 composite materials stabilizes around 350° C., slightly higher for the TiO₂-F127 composite material. The detectable weight loss between 350° C. and 400° C. was ˜0.61 wt % for TiO₂-F127 and ˜0.46 wt % for TiO₂-P123. For the interval between 400° C. and 450° C., the loss drops to ˜0.29 wt % and ˜0.08 wt %, respectively. This indicates that with the annealing temperatures used the polycrystalline TiO₂ structure has been fully formed and the polymer has been burnt out of the inorganic matrix, except for possibly small amounts of trace residues in the low temperature material (350° C.).

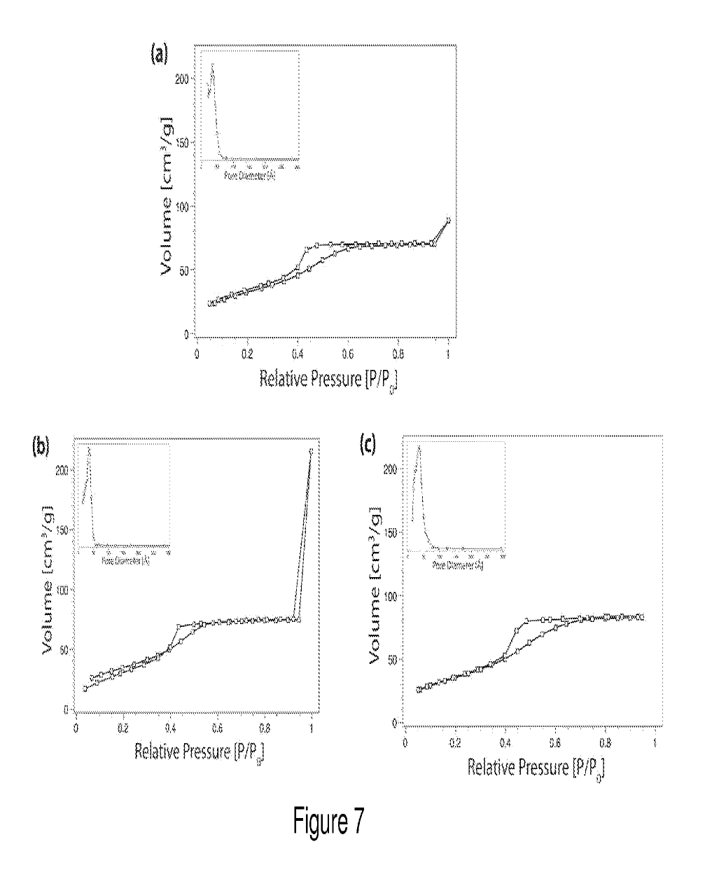

Consequently, the changes in refractive index of a given TiO₂ film may result from a combination of variation in size and density of the mesopores within a condensed TiO₂ matrix. Brunauer-Emmett-Teller (BET) adsorption pore diameters, adsorption pore volume, and surface area were determined from N₂ adsorption isotherms for the bulk mesoporous TiO₂ synthesized using Pluronic® F127 block copolymer or Pluronic® P123 block copolymer as templating polymers (Table 1). FIG. 7 depicts N₂ adsorption isotherms and pore diameter distribution (insets) for TiO₂-F127 bulk materials annealed at (a) 350° C., (b) 400° C. and (c) 450° C., respectively. All adsorption curves display a hysteresis loop, which is indicative of mesoporous (pore opening >2 nm) or macroporous (pore opening >50 nm) materials.

The pore sizes observed for the different TiO₂ bulk materials (Table 1) generally become larger with increasing annealing temperatures. With increasing crystallinity of the material, smaller voids are annealed out and fuse with other pores, resulting in an increase in the observed overall pore size. Comparing the refractive indices of different materials annealed at the same maximum temperature, the refractive index increases in the order TiO₂-2xP123<TiO₂-F127≦TiO₂-P213.

Densification due to hydrolysis and condensation of the TiO₂ matrix may reach its conclusion at ˜350° C., which is approximately the same temperature at which most or all of the organic matter of the templating tri-block copolymers has been removed from the spincoated thin films. It was observed that for materials annealed at 350° C., the pore size increases in the order TiO₂-F127<TiO₂-P123<TiO₂-2xP213 (Table 1).

Although pore size in the mesoporous material may be a dominant parameter affecting the refractive index, the pore volume of a material, which can be taken as a measure of pore density, might be another factor influencing the optical properties of the mesoporous TiO₂ films prepared from spincoated sol-gel solutions (Table 1). Measured film thickness, calculated individual pore volume, assuming spherical pores, and the number of pores per gram of TiO₂ bulk material are summarized in Table 2. Pore density was calculated by dividing the measured pore volume per gram by the individual pore volume (calculated from the pore size).

TABLE 2
Film thickness, calculated volume of an individual pore, and pore
density [(number of pores)/g] for mesoporous TiO₂
bulk materials prepared by sol-gel synthesis using Pluronic ®
F127 block copolymer and Pluronic ® P123 block
copolymer fillers, respectively, as templating agents. Values are
calculated from experimental data listed in Table 1.

| | TiO₂- | TiO₂- | TiO₂- | TiO₂- | TiO₂- | TiO₂- | TiO₂- |
|---|---|---|---|---|---|---|---|
| | F127 | F127 | F127 | P123 | P123 | P123 | 2xP123 |
| | (350° C.) | (400° C.) | (450° C.) | (350° C.) | (400° C.) | (450° C.) | (350° C.) |
| Film | 402 | 350 | 350 | 185 | 175 | 173 | 305 |
| thickness | | | | | | | |
| [nm] | | | | | | | |
| Individual | 20.40 | 27.90 | 28.48 | 44.04 | 41.43 | 58.56 | 58.45 |
| pore | | | | | | | |
| volume | | | | | | | |
| [nm³] | | | | | | | |
| Pore | 7.1 | 12.2 | 4.7 | 1.9 | 4.0 | 2.2 | 4.0 |
| density [(# | | | | | | | |
| of pores/g) = | | | | | | | |
| 10¹⁸] | | | | | | | |

TiO₂-F127 and TiO₂-P123 materials show the highest pore densities for the bulk materials annealed at 400° C. (Table 2). The difference is more pronounced in TiO₂-F127, which may be due to the increase in overall pore volume (Table 1). Compared to materials annealed at 350° C., these samples contain no residues of organic matter. This results in additional smaller voids within the material and increases the porosity of the TiO₂ matrix. Between 400-450° C. the pores may begin to coalesce together, and as the individual pore volume, as well as the crystalline correlation length of the TiO₂, increases, the pore density decreases. Thus, the pore density peaks around 400° C. for the TiO₂-F127 and TiO₂-P123 materials.

Considering TiO₂-P123 films annealed at 350° C. and 400° C., respectively, which have a very similar pore size (4.283 Å vs. 4.293 Å), it appears that a thinner film (TiO₂-P123 annealed at 400° C., 175 nm) with a higher pore density (4.0□10¹⁸ pores/g) has the same refractive index as a thicker film (TiO₂-P123 annealed at 350° C., 185 nm) with a lower pore density (1.9□10¹⁸ pores/g), n=1.73 in both cases. On the other hand, two films that have the same pore size, like TiO₂-P123 annealed at 450° C. and TiO₂-2xP123 annealed at 350° C., exhibit different refractive indices if the thicker film (TiO₂-2xP123 annealed at 350° C., 305 nm vs. 173 nm for TiO₂-P123 annealed at 450° C.) has the higher pore density (4.0□10¹⁸ pores/g vs. 2.2□10¹⁸ pores/g for TiO₂-P123 annealed at 450° C.). n=1.68 for the thinner TiO₂-P123 film and n=1.61 for the thicker TiO₂-2xP123. The size of the pores within the different TiO₂ bulk materials (Table 1) generally becomes larger with increasing annealing temperatures as smaller pores coalesce into larger pores.

Thus, the index of refraction may also be a function of the pore density in addition to the correlation between the refractive index and the pore size. Films of similar thickness but with a higher pore density may exhibit a lower refractive index. The refractive index for mesoporous materials may also be a function of measurement angle.

1. A light-emitting device comprising:
a substrate;
a transparent conducting material; and
at least one light extraction layer comprising at least one porous metal or metalloid oxide, wherein the at least one light extraction layer is disposed between the substrate and the transparent Conducting material.

2. The light-emitting device according to claim 1, wherein the at least one porous metal or metalloid oxide is comprised of: titania, silica, zinc oxide, aluminum oxide, zirconium oxide, lanthanum oxide, niobium oxide, tungsten oxide, tin oxide, indium oxide, strontium oxide, vanadium oxide, molybdenum oxide, calcium oxide, or blends of two or more such materials.

3. The light-emitting device according to claim 1, wherein the at least one porous metal or metalloid oxide is a mesoporous layer.

4. The light-emitting device according to claim 1, wherein the at least one light extraction layer comprises titania.

5. The light-emitting device according to claim 1, wherein the at least one porous metal or metalloid oxide comprises at least one metal or metalloid oxide having a first refractive index and pores having a second refractive index and the difference between the first refractive index of the at least one metal or metalloid oxide and the second refractive index of the pores is 0.5 or greater in the visible wavelength region.

6. The light-emitting device according to claim 1, wherein the at least one light extraction layer is densified at a region adjacent an interface with another layer.

7. The light-emitting device according to claim 6, wherein the densified region comprises a refractive index nigher than a remainder of the at least one light extraction layer.

8. The light-emitting device according to claim 1, wherein the at least one light extraction layer comprises an interface between at least a first light extraction layer and a second light extraction layer and the at least one light extraction layer is densified at a region adjacent the interface.

9. The light-emitting device according to claim 1, wherein the at least one light extraction layer is densified at a region adjacent an interface between the at least one light extraction layer and the substrate.

10. The light-emitting device according to claim 1, wherein the at least one light extraction layer has a gradient of refractive indexes with a higher refractive index adjacent the transparent conducting material and a lower refractive index adjacent the substrate.

11. The light-emitting device according to claim 1, wherein the at least one light extraction layer comprises more than one porous metal or metalloid oxide layer and each layer of the porous metal or metalloid oxide layers has a gradient of refractive indexes.

12. The light-emitting device according to claim 1, wherein the at least one light extraction layer comprises more than one porous metal or metalloid oxide layer and each layer of the porous metal or metalloid oxide layers consists of the same materials and pore structure.

13. The light-emitting device according to claim 1, wherein the at least one light extraction layer comprises more than one porous metal or metalloid oxide layer and each layer of the porous metal or metalloid oxide layers consists of different materials or pore structure.

14. The light-emitting device according to claim 1, wherein the at least one porous metal or metalloid oxide comprises pores that are less than about 500 nm.

15. The light-emitting device according to claim 1, wherein the at least one porous metal or metalloid oxide comprises pores ranging from about 20-50 nm.

16. The light-emitting device according to claim 1, Wherein the at least one porous metal or metalloid oxide comprises pores that are less than about 20 nm.

17. The light-emitting device according to claim 1, wherein the at least one porous metal or metalloid oxide comprises pores that are less than about 10 nm.

18. The light-emitting device according to claim 1, wherein the at least one light extraction layer comprises pores ranging from about 5-8 nm.

19. The light-emitting device according to claim 1, wherein the at least one porous metal or metalloid oxide comprises open or closed cell pores filled with a different refractive index material.

20. The light-emitting device according to claim 1, wherein the at least one porous metal or metalloid oxide comprises pores filled with the transparent conducting material.

21. The light-emitting device according to claim 1, wherein at an interface of the at least one light extraction layer and the transparent conducting material, a region of the at least one light extraction layer adjacent the interface comprises less than 10 nm pores filled with the transparent conducting material.

22. The light-emitting device according to claim 1, wherein the at least one porous metal or metalloid oxide comprises a metal or metalloid oxide dopant.

23. The light-emitting device according to claim 1, wherein the at least one light extraction layer is between about 50 nm and about 1000 nm in thickness.

24. The light-emitting device according to claim 1, wherein the transparent conducting material comprises doped zinc oxide, indium tin oxide, indium zinc oxide, fluorine-doped tin oxide, niobium-doped titanium dioxide, graphene, carbon nanotubes, or silver film or silver nanostructures.

25. The light-emitting device according to claim 1, wherein the light-emitting device includes an organic light emitting diode (OLED) and the at least one light extraction layer improves the external quantum efficiency (EQE) of the OLED over the range of 300 nm to 1200 nm.

26. A light-emitting device comprising:
a substrate;
a transparent conducting oxide; and
at least one mesoporous light extraction layer comprising a mesoporous titania, wherein the at least one mesoporous light extraction layer is disposed between the substrate and the transparent conducting oxide.

27. A method for forming a light-emitting device, the method comprising:
forming at least one light extraction layer comprising a porous metal or metalloid oxide on a substrate; and
forming a transparent conducting material on the at least one light extraction layer.

28. The method according to claim 27 further comprising:
forming at least one layer comprising an organic layer on the transparent conducting material; and forming an electrode layer on the at least one layer.

29. The method according to claim 27, wherein the at least one light extraction layer is formed by solution processing, chemical vapor deposition, physical vapor deposition, or vacuum thermal evaporation.

30. The method according to claim 27, wherein the at least one index of refraction of the at least one light extraction layer is tuned by at least one of i) changing the pore size; ii) compositional doping; iii) adding an insulating, conducting or semiconducting component; iv) filling the pores; v) changing the pore density; vi) changing the thickness; or combinations thereof.

31. The method according to claim 27, wherein the porous metal or metalloid oxide is formed from a sol gel solution comprising a surfactant template and/or a hard polymer template.

32. The method according to claim 31, wherein the surfactant template comprises an amphiphilic tri-block copolymer comprising a polypropylene oxide) segment capped by poly(ethylene oxide) segments on each end.

33. A method of extracting light from an OLED device, the method comprising:
adding at least one internal light extraction layer comprising a porous metal or metalloid oxide between two adjacent layers in the OLED device, wherein the at least one internal light extraction layer is added between at least one of a transparent conducting oxide (TCO)-substrate interface or a TCO-organic interface.

34. A method of providing a light extraction layer in a light-emitting device comprising:
varying at least one of pore size and pore density of a porous metal oxide to obtain at least one refractive index and light scattering for a light extraction layer comprising the porous metal oxide, wherein the light extraction layer is positioned between a substrate and a transparent conducting oxide.

35. The method according to claim 34, wherein at least one of the pore size and the pore density of the porous metal oxide is varied by selection of at least one of a surfactant template, a concentration of the surfactant template, and at least one annealing temperature.

36. The method according to claim 35, wherein the at least one annealing temperature is between 300 and 500° C.

37. The method according to claim 36, wherein the porous metal oxide undergoes a plurality of annealing treatments.
